(19) United States
(12) Patent Application Publication
(10) Pub. No.: US 2026/0299017 A1
(43) Pub. Date: Oct. 1, 2026

(54) COMPOSITE INTERFACE SUBSTRATE FOR A PROBE CARD AND METHODS FOR FORMING AND OPERATING THE SAME

(71) Applicant: Taiwan Semiconductor Manufacturing Company Limited, Hsinchu (TW)

(72) Inventors: Cheng-Hui CHANG, Hsinchu (TW); Kuan Chun CHEN, Hsinchu (TW); Yu-Hsuan CHENG, Hsinchu (TW); Kai-Yi TANG, New Taipei City (TW)

(21) Appl. No.: 19/093,715

(22) Filed: Mar. 28, 2025

(51) Int. Cl. G01R 31/28; G01R 1/073; G01R 3/00

(52) U.S. Cl. CPC G01R 31/2889; G01R 1/07342; G01R 3/00

(57) ABSTRACT

A test apparatus may be operated by: providing a bonded assembly of a proximal interface substrate and a distal interface substrate, wherein the proximal interface substrate includes a silicon layer, first metal interconnect structures, and probe contact pads, and the distal interface substrate includes a high-hardness dielectric layer and second metal interconnect structures, the high-hardness dielectric layer has a Vickers hardness greater than 500 HV, and the second metal interconnect structures are electrically connected to the first metal interconnect structures; and disposing an array of probe needles on the probe contact pads.

### BACKGROUND

A semiconductor test apparatus may use a probe card to establish electrical contact with test pads on a device under test (DUT), which may be a semiconductor die. As semiconductor devices become increasingly complex, testing requires precise alignment and reliable electrical connections. Related probe cards often incorporate multi-layer organic substrates to provide an electrical interface between the test apparatus and the DUT. However, multi-layer organic substrates suffer from limitations such as inadequate flatness, large spacing, and high coefficients of thermal expansion. These deficiencies may lead to misalignment, frequent contact failures at elevated temperatures, and reduced circuit density, ultimately limiting the efficiency and throughput of testing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a test apparatus according to an embodiment of the present disclosure.

FIG. 2A-2C illustrate a sequence of processing steps that may be used to manufacture a bonded assembly of a proximal interface substrate and a distal interface substrate, and to attach the bonded assembly to a printed circuit board according to an embodiment of the present disclosure.

FIG. 3A is a vertical cross-sectional view of a first exemplary probe assembly according to an embodiment of the present disclosure. FIG. 3B is a horizontal cross-sectional view along the horizontal plane B-B′ of the first exemplary probe assembly of FIG. 3A. The vertical plane A-A′ in FIG. 3B is the cut plane of the vertical cross-sectional view of FIG. 3A. FIG. 3C is a horizontal cross-sectional view along the horizontal plane C-C′ of the first exemplary probe assembly of FIG. 3A. The vertical plane A-A′ in FIG. 3C is the cut plane of the vertical cross-sectional view of FIG. 3A. FIG. 3D is a horizontal cross-sectional view along the horizontal plane D-D′ of the first exemplary probe assembly of FIG. 3A. The vertical plane A-A′ in FIG. 3D is the cut plane of the vertical cross-sectional view of FIG. 3A. FIG. 3E is a magnified view of an upper portion of a probe card within the first exemplary probe assembly of FIG. 3A-3D. FIG. 3F is a first alternative configuration of the first exemplary probe assembly according to an embodiment of the present disclosure. FIG. 3G is a second alternative configuration of the first exemplary probe assembly according to an embodiment of the present disclosure.

FIG. 4A is a vertical cross-sectional view of a second exemplary probe assembly according to an embodiment of the present disclosure. FIG. 4B is a magnified view of an upper portion of a probe card within the second exemplary probe assembly of FIG. 4A. FIG. 4C is a first alternative configuration of the second exemplary probe assembly according to an embodiment of the present disclosure. FIG. 4D is a second alternative configuration of the second exemplary probe assembly according to an embodiment of the present disclosure.

FIG. 5A-5F are sequential vertical cross-sectional views of an exemplary structure that is converted into a composite interface substrate according to an embodiment of the present disclosure.

FIG. 6A is a vertical cross-sectional view of a third exemplary probe assembly according to an embodiment of the present disclosure. FIG. 6B is a magnified view of an upper portion of a probe card within the third exemplary probe assembly of FIG. 5A. FIG. 6C is a first alternative configuration of the third exemplary probe assembly according to an embodiment of the present disclosure. FIG. 6D is a second alternative configuration of the third exemplary probe assembly according to an embodiment of the present disclosure.

FIG. 7A is a plan view of a wafer after formation of test pads according to an embodiment of the present disclosure. FIG. 7B is a vertical cross-sectional view of the wafer along the vertical plane B-B′ of FIG. 7A.

FIG. 8 is a vertical cross-sectional view of a portion of the test apparatus of FIG. 1 during testing of a semiconductor die using test pads on the wafer according to an embodiment of the present disclosure.

FIG. 9 is a first flowchart that illustrates the general processing steps for operating a test apparatus according to an aspect of the present disclosure.

FIG. 10 is a second flowchart that illustrates the general processing steps for manufacturing a test apparatus according to an aspect of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element if the entire volume of the first element is located within a hypothetical volume defined by a set of hypothetical surfaces having the least total surface area selected from all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment selected from all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Related interface substrates for probe cards use a soft material that easily deforms to accommodate local stress. Polyethylene terephthalate (PET), commonly known as mylar, has a Vickers hardness in the range from 10 HV to 20 HV. While the deformation in the soft material for the traditional interface substrates may be conductive to manual alignment of probe needles to probe contact pads, the soft material also deforms easily at high temperature, and oftentimes causes misalignment between the probe needles and the probe contact pads at elevated temperatures, thereby degrading the probe performance at elevated temperatures.

Embodiments of the present disclosure are directed to a composite interface substrate for a probe card for improving the performance of the probe card in semiconductor testing. Specifically, the composite interface substrate includes a bonded assembly of a proximal interface substrate and a distal interface substrate. The composite interface substrate of the present disclosure enhances thermal stability, circuit density, and flatness in a probe card assembly. The proximal interface substrate comprises a silicon layer, first metal interconnect structures, and probe contact pads, while the distal interface substrate comprises a high-hardness dielectric layer and second metal interconnect structures. The high-hardness dielectric layer of the distal interface substrate has a higher Vickers hardness than the silicon layer, and the second metal interconnect structures are electrically connected to the first metal interconnect structures. The composite interface substrate of the present disclosure is integrated with a printed circuit board (PCB) and an array of probe needles to provide a probe card assembly. The composite interface substrate of the present disclosure provides enhanced alignment precision, reduced warpage, and increased circuit density.

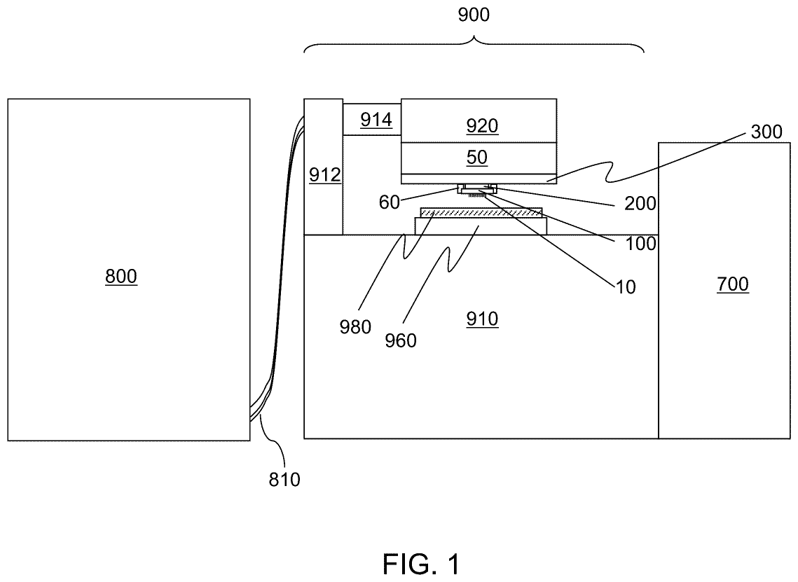

Referring to FIG. 1, an embodiment test apparatus illustrating an aspect of the present disclosure is provided. The embodiment test apparatus may include a tester electronics unit 800 including at least one computer and peripheral devices, a wafer prober 900 in communication with the tester electronics unit 800, for example, via signal and power cables 810, and an optional wafer conveyer unit 700 configured to load and unload a device under test (DUT) 980 to be tested on the wafer prober 900. The wafer prober 900 may include a wafer chuck 960 configured to hold a device under test (DUT) 980 thereupon, a prober frame 910 containing a stage drive unit configured to laterally drive the wafer chuck 960, a tester head 920 that overlies the wafer chuck 960, and tester head support structures (912, 914) configured to structurally support, and to provide movement to, the tester head 920.

The probe card 300 may comprise a printed circuit board (PCB) containing a plastic substrate and printed circuits thereupon. The probe card 300 is commonly referred to as a main board. A probe interface assembly (10, 100, 200, 60) may be attached to the bottom of the probe card 300. The probe interface assembly (10, 100, 200, 60) comprises a composite interface substrate 200, a plate assembly 100 including an upper guide plate, a lower guide plate, and a plurality of dielectric spacer plates, a jig 60 configured to affix the plate assembly 100 to the probe card 300, and an array of probe needles 10. The combination of the probe interface assembly (10, 100, 200, 60) and the probe card 300 constitutes a probe card assembly (10, 100, 200, 60, 300).

A probe support assembly 50 may be attached to the top of the probe card 300. The probe support assembly 50 may comprise a stiffener (not expressly illustrated in FIG. 1), which may be attached to the backside of the probe card 300 to reduce structural deformation of the probe card 300 due to thermal and/or mechanical stress during use of the probe card 300. The probe support assembly 50 may be subsequently attached to the bottom of the tester head 920 using a suitable array of contact structures such as an array of spring-type contact pins. The combination of the probe card assembly (10, 100, 200, 60, 300) and the probe support assembly 50 is herein referred to as a probe module assembly (10, 100, 200, 60, 300, 50). According to an aspect of the present disclosure, the probe module assembly (10, 100, 200, 60, 300, 50) of the present disclosure is configured to enhance the planarity and stability of a probe card assembly (10, 100, 200, 60, 300) during wafer probing.

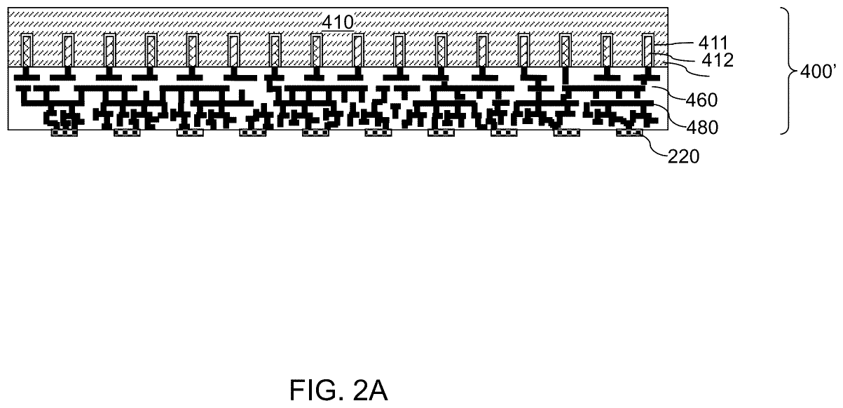

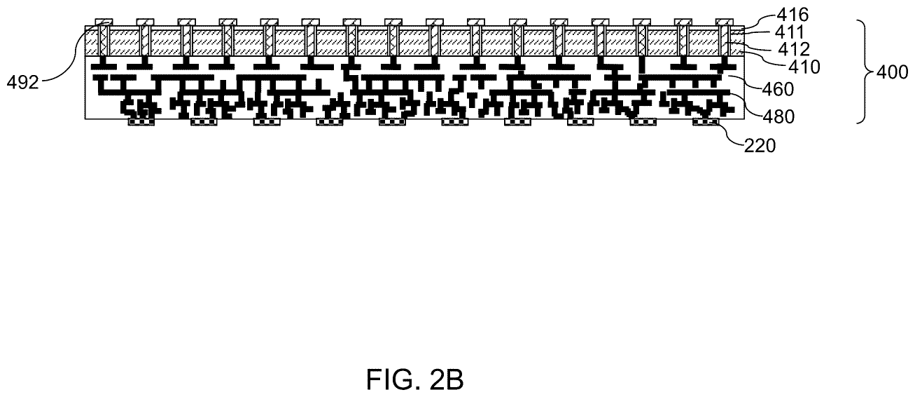

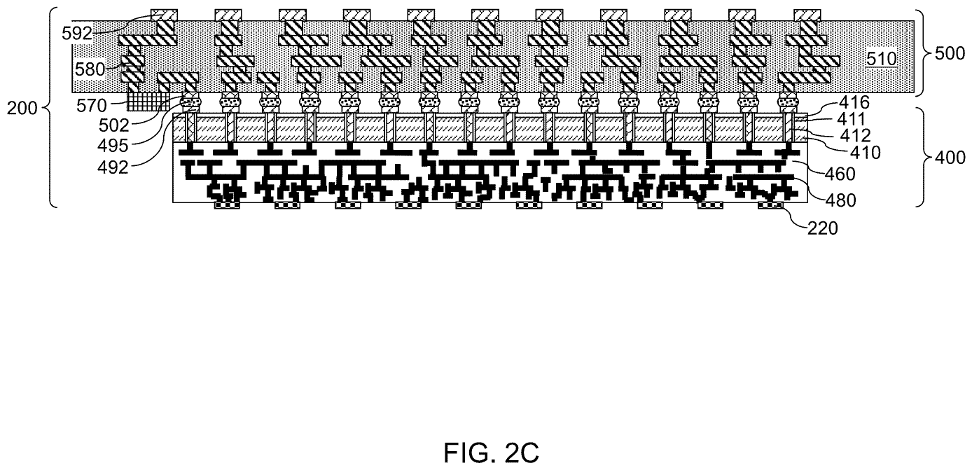

FIG. 2A-2C illustrate a sequence of processing steps that may be used to manufacture a bonded assembly of a proximal interface substrate 400 and a distal interface substrate 500, and to attach the bonded assembly (400, 500) to a printed circuit board 300 according to an embodiment of the present disclosure.

Referring to FIG. 2A, an in-process proximal interface substrate 400′ is illustrated, which comprises a silicon layer 410. The silicon layer 410 may be provided as a portion of a silicon substrate, on which a two-dimensional array of in-process proximal interface substrates 400′ may be formed. A single in-process proximal interface substrate 400′ is illustrated in FIG. 2A. Deep trenches may be formed on the front side of the silicon substrate. Each of the deep trenches may be filled with a combination of a respective dielectric liner 411 and a respective through-substrate via (TSV) structure 412. First dielectric material layers 460 and first metal interconnect structures 480 may be formed over the silicon substrate. In one embodiment, the first dielectric material layers 460 may comprise, and/or may consist essentially of, at least one dielectric material having a respective Vickers hardness less than the Vickers hardness of silicon (which is approximately 1,200 HV). In one embodiment, the ILS layers 460 have an average Vickers hardness less than the Vickers hardness of silicon. In one embodiment, the first dielectric material layers 460 may be composed primarily of silicon oxide, which has Vickers hardness of about 1,000 HV.

Probe contact pads 220 may be formed directly on a subset of the first metal interconnect structures 480. For example, the probe contact pads 220 may be formed on the topmost subset of the first metal interconnect structures 480. The first metal interconnect structures 480 comprise at least one metallic material such as tungsten and/or copper. The probe contact pads 220 may comprise gold pads.

Referring to FIG. 2B, the semiconductor substrate may be thinned from the backside until bottom ends of the TSV structures 412 are physically exposed. The backside portion of the semiconductor substrate may be removed, for example, by grinding, polishing, an isotropic etch process, or an anisotropic etch process. A recess etch process may be performed to vertically recess the backside surface of the semiconductor substrate. A backside insulating layer 416 may be deposited on the backside surface of the semiconductor substrate and the physically exposed end surfaces of the TSV structures 412. A chemical mechanical polishing process may be performed to physically expose the bottom surfaces of the TSV structures 412. Optionally, metallic bonding pads 492 may be formed on the physically exposed bottom surfaces of the TSV structures 412. The metallic bonding pads 492 may comprise microbump structures or C4 bonding pads. Alternatively, the metallic bonding pads 492 may comprise bonding pads configured for metal-to-metal bonding, such as copper-to-copper bonding.

A two-dimensional array of proximal interface substrates 400 may be formed on the silicon substrate. The proximal interface substrates 400 may be singulated by dicing the silicon substrate along dicing channels. The single proximal interface substrate 400 illustrated in FIG. 2B may be one of the proximal interface substrate 400 that are formed by dicing. Generally, a proximal interface substrate 400 comprising a silicon layer 410, first metal interconnect structures 480, and probe contact pads 220 is provided. In one embodiment, the proximal interface substrate 400 comprises an array of through-substrate via (TSV) structures 412.

Referring to FIG. 2C, a distal interface substrate 500 is provided. The distal interface substrate 500 comprises a high-hardness dielectric layer 510 and second metal interconnect structures 580 that are formed in the high-hardness dielectric layer 510. In one embodiment, the high-hardness dielectric layer 510 comprises a high-hardness dielectric material that is selected from silicon nitride, silicon carbide, aluminum nitride, dielectric metal oxides, a mullite-cordierite composite, and a ceramic material. According to an aspect of the present disclosure, the high-hardness dielectric layer 510 has a Vickers hardness greater than 500 HV. In one embodiment, the high-hardness dielectric layer 510 comprises, and/or consists essentially of, a dielectric material having a higher Vickers hardness than silicon oxide.

Vickers hardness is a measure of a material's resistance to deformation when subjected to a specified load. This test involves pressing a diamond pyramid-shaped indenter into the surface of the material and measuring the resulting indentation. The Vickers hardness number (VHN) is calculated by dividing the applied force (F) by the area (A) of the indentation, which is determined based on the size of the indentation made by the pyramid indenter. The formula for calculating the Vickers hardness number is: VHN=F/A, where F is the applied force (in kilograms or Newtons), and A is the area of the indentation (in square millimeters). The Vickers hardness test is suitable for a wide range of materials, including metals, ceramics, and composites. It is commonly used in materials science and engineering for determining the hardness of both soft and hard materials, providing valuable data for the selection and evaluation of materials in various applications. The Vickers hardness number (VHN) is typically expressed in kilograms-force per square millimeter (kgf/mm²) or in SI units as Newtons per square millimeter (N/mm²). A unit of Vickers hardness is HV. 1 HV (Vickers Hardness) is defined as the amount of pressure required to create a specific indentation on a material's surface, and it is measured in kilograms of force (kgf) per square millimeter (kgf/mm²). This value corresponds to the pressure applied by a diamond indenter with a square base, under a specified load, to create an indentation on the material being tested. 1 kilogram-force (kgf) equals 9.807 Newtons. Thus, 1 HV equals 9.807 GPa.

In one embodiment, the high-hardness dielectric layer 510 comprises a material that is selected from silicon oxide, silicon nitride, silicon carbide, dielectric metal oxides, and ceramic materials, and having Vickers hardness greater than 500 HV. The Vickers hardness of silicon is approximately 1,200 HV. The Vickers hardness of silicon oxide (in amorphous form as in silicate glass used as ILD materials) is about 1,000 HV. The Vickers hardness of silicon nitride is typically in the range from 1,200 HV to 2,500 HV, depending on the specific type of silicon nitride. The Vickers hardness of aluminum oxide is 1,175 HV. The Vickers hardness of aluminum nitride is 1,100 HV. The Vickers hardness of zirconium oxide is 1,300 HV. The Vickers hardness of hafnium oxide is in a range from 1,450 HV to 2,100 HV. The Vickers hardness of titanium oxide is about 1,200 HV. The Vickers hardness of tantalum oxide is about 1,200, HV. Mullites refer to a class of alumino-silicate compounds that are often used for their high-temperature stability. Mullites typically have Vickers hardness in a range from 800 HV to 1,500 HV, depending on composition. Cordierites refer to magnesium aluminum silicate materials known for their low thermal expansion and thermal shock resistance. Cordierites have Vickers hardness in a range from 800 HV to 1,000 HV. The Vickers hardness of dielectric metal oxide materials may be in a range from 500 HV to 2,000 HV, depending on the specific oxide material. Ceramic materials having a Vickers hardness higher than silicon oxide include alumina and zirconia. In one embodiment, the high-hardness dielectric layer 510 comprises a material having a higher Vickers hardness than silicon oxide.

A high Vickers hardness in the material of the high-hardness dielectric layer 510 offers enhanced mechanical stability for the probe card assembly to be formed. Vickers hardness measures a material's resistance to deformation under applied load, and is a measure for the mechanical stability and longevity of components subjected to high-stress conditions. Materials with higher Vickers hardness are more resistant to wear and surface deformation, reducing the risk of scratching, gouging, or other damage during testing, thereby extending the lifespan of the probe card. Additionally, such materials provide better structural integrity, allowing the device to withstand mechanical stresses and thermal cycles without warping or misalignment, which helps maintain accurate probe-to-pad alignment. When combined with low thermal expansion materials, the distal interface substrates 500 also contribute to better thermal performance, as they are more stable under thermal stress and less likely to experience expansion or contraction that could affect test accuracy. Furthermore, higher hardness materials offer increased resistance to external forces, such as pressure or impact, ensuring the probe needles 10 maintain precise contact with the probe contact pads 220 and enhancing the overall reliability and durability of the testing process.

In one embodiment, the high-hardness dielectric layer 510 comprises a material that is selected from silicon oxide, silicon nitride, silicon carbide, dielectric metal oxides, and ceramic materials, and having a coefficient of thermal expansion (CTE) not greater than 1.0×10⁻⁵/° C. The CTE of silicon is approximately 2.6×10⁻⁶/° C. The CTE of silicon oxide is typically in the range from 0.5×10⁻⁶/° C. to 1.0×10⁻⁶/° C. The CTE of silicon nitride is typically in the range from 2.5×10⁻⁶/° C. to 3.0×10⁻⁶/° C., depending on the specific type of silicon nitride. The CTE of dielectric metal oxide materials may be in a range from 1.0×10⁻⁶/° C. to 2.5×10⁻⁶/° C., depending on the specific oxide material. Ceramic materials having a CTE lower than silicon include alumina (8.0×10⁻⁶/° C.-10.0×10⁻⁶/° C.) and zirconia (10.0×10⁻⁶/° C.-11.0×10⁻⁶/° C.). In one embodiment, the high-hardness dielectric layer 510 comprises a material having a lower CTE than silicon.

A low CTE in the material of the high-hardness dielectric layer 510 offers additional enhanced mechanical stability for the probe card assembly to be formed. CTE measures a material's dimensional change with temperature variation and is a measure for the thermal stability and longevity of components subjected to temperature fluctuations. Materials with lower CTE are more stable under thermal stress, reducing the risk of warping, expansion, or contraction that could affect the probe-to-pad alignment. Enhanced mechanical stability provided by the low CTE helps maintain accurate testing conditions, even during thermal cycles. Additionally, a low CTE material in the high-hardness dielectric layer 510 provides better structural integrity, allowing the probe card assembly to withstand mechanical stresses without warping or misalignment. Use of a low CTE material for the high-hardness dielectric layer 510 increases the overall thermal performance of the probe card assembly, and reduces deformation of the probe card assembly under temperature fluctuations. Furthermore, a low CTE material in the high-hardness dielectric layer 510 allows precise contact with the probe contact pads 220 at elevated temperatures, enhancing the overall reliability and durability of the testing process.

The distal interface substrate 500 is resistant to warpage, and thus, remains flat. For example, the thickness variation of the distal interface substrate 500 may be less than 10 microns, and the warpage of the distal interface substrate 500 from the center to the edge may be less than 20 microns. The second metal interconnect structures 580 formed within the high-hardness dielectric layer 510 may include metal lines and metal via structures. The total numbers of levels of the metal lines within the high-hardness dielectric layer 510 may be in a range from 1 to 12, and the total number of levels of metal via structures within the high-hardness dielectric layer 510 may be in a range from 1 to 11. The widths of the second metal interconnect structures 580 may be in a range from 2 nm to 20 microns, although lesser and greater widths may also be used.

Electrical components 570 may be attached to physically exposed metallic surfaces of the second metal interconnect structures 580. The electrical components 570 may comprise capacitors, resistors, inductors, or any other passive electrical components known in the art. Solder bonding pads 592 may be provided on the side of the distal interface substrate 500 to be subsequently bonded to a probe card 300. The solder bonding pads 592 may comprise copper pads. Metallic bonding structures are provided on the opposite side of the distal interface substrate 500. In one embodiment, the metallic bonding structures may comprise additional metallic bonding pads 502, which may be microbump structures or C4 bonding pads. Alternatively, the metallic bonding structures may comprise bonding pads configured for metal-to-metal bonding, such as copper-to-copper bonding.

A proximal interface substrate 400 as provided at the processing steps of FIG. 2B may be bonded to the distal interface substrate 500. Various bonding methods may be used to bond the proximal interface substrate 400 to the distal interface substrate 500. In one embodiment, the metallic bonding pads 492 of the proximal interface substrate 400 may comprise first solder bonding pads, and the metallic bonding pads 502 of the distal interface substrate 500 may comprise second solder bonding pads. In one embodiment, solder bonding may be performed using an array of solder material portions 495 between the metallic bonding pads 492 of the proximal interface substrate 400 and the metallic bonding pads 502 of the distal interface substrate 500 such that the proximal interface substrate 400 is bonded to the distal interface substrate 500.

Generally, the distal interface substrate 500 is bonded to the proximal interface substrate 400 such that the second metal interconnect structures 580 are electrically connected to the first metal interconnect structures 480. In one embodiment, the distal interface substrate 500 may be bonded to the proximal interface substrate through solder-mediated bonding, i.e., bonding employing an array of reflowed solder material portions. The second metal interconnect structures 580 in the distal interface substrate 500 are electrically connected to the probe contact pads 220 through the first metal interconnect structures 480 and the TSV structures 412. The second metal interconnect structures 580 in the distal interface substrate 500 may be electrically connected to a respective one of the TSV structures 412 upon bonding the distal interface substrate 500 to the proximal interface substrate 400. The second metal interconnect structures 580 provide fine-pitch electrical traces that provide electrical connections between the probe contact pads 220 and the solder bonding pads 592. The bonded assembly of the proximal interface substrate 400 and the distal interface substrate 500 constitutes a composite interface substrate 200.

Referring collectively to FIG. 2A-2C, a proximal interface substrate 400 comprising a silicon layer 410 and first metal interconnect structures 480 may be provided. A distal interface substrate 500 comprising a high-hardness dielectric layer 510 and second metal interconnect structures 580 may be provided. The high-hardness dielectric layer 510 has a Vickers hardness greater than 500 HV. The distal interface substrate 500 may be bonded to the proximal interface substrate 400 such that the second metal interconnect structures 580 are electrically connected to the first metal interconnect structures 480. In one embodiment, the proximal interface substrate 400 comprises first solder bonding pads, the distal interface substrate 500 comprises second solder bonding pads, and solder bonding may be performed using an array of solder material portions 495 between the first solder bonding pads and the second solder bonding pads such that the proximal interface substrate 400 is bonded to the distal interface substrate 500.

A bonded assembly of a proximal interface substrate 400 and a distal interface substrate 500 may be provided. The proximal interface substrate 400 comprises a silicon layer 410, first metal interconnect structures 480, and probe contact pads 220. The distal interface substrate 500 comprises a high-hardness dielectric layer 510 and second metal interconnect structures 580. In one embodiment, the high-hardness dielectric layer 510 has a Vickers hardness greater than 500 HV, and the second metal interconnect structures 580 are electrically connected to the first metal interconnect structures 480. An array of probe needles 10 may be disposed on the probe contact pads 220. Generally, the proximal interface substrate 400 comprises first dielectric material layers within which the first metal interconnect structures 480 are located. The probe contact pads 220 are located directly on a subset of the first metal interconnect structures 480.

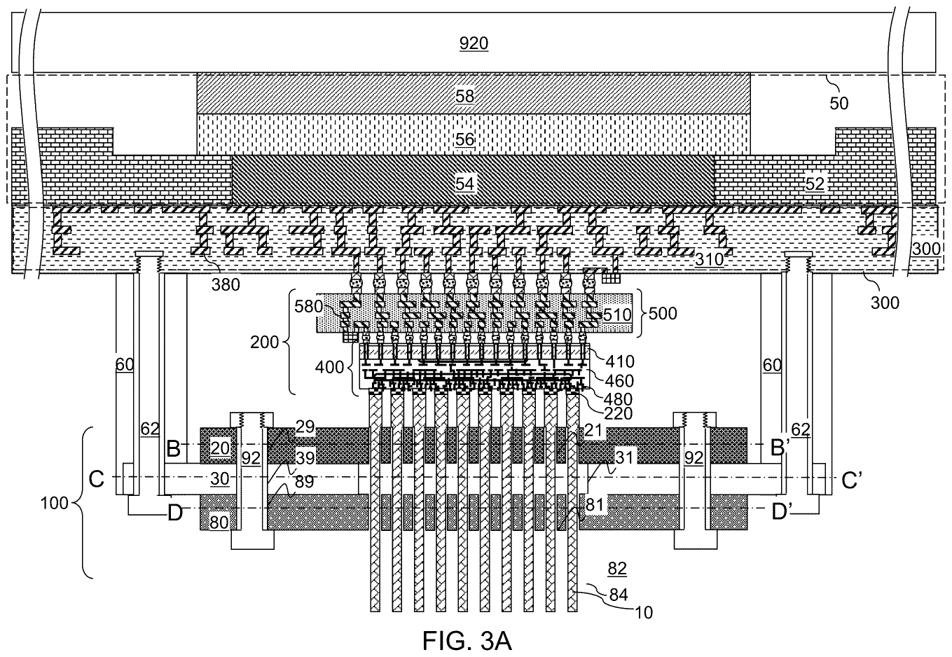

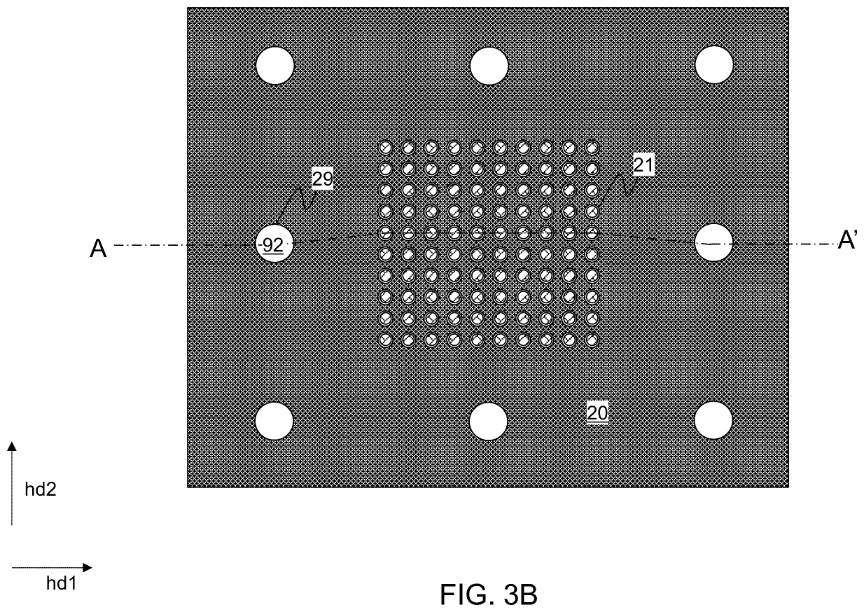

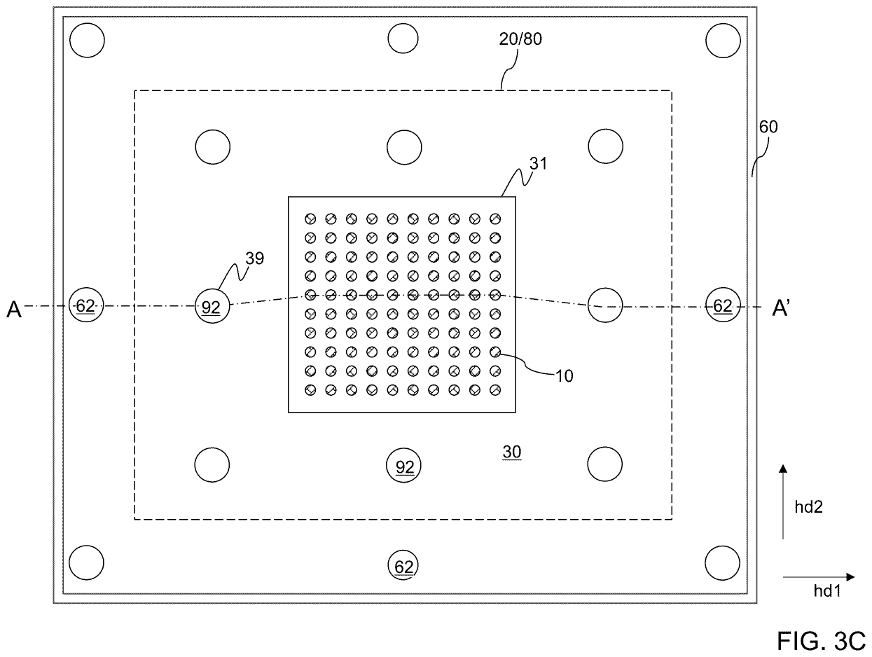

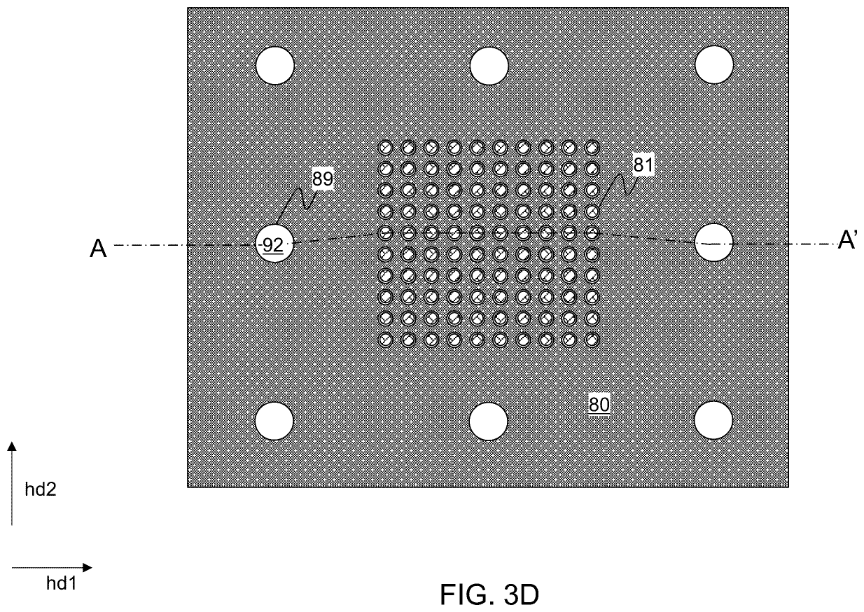

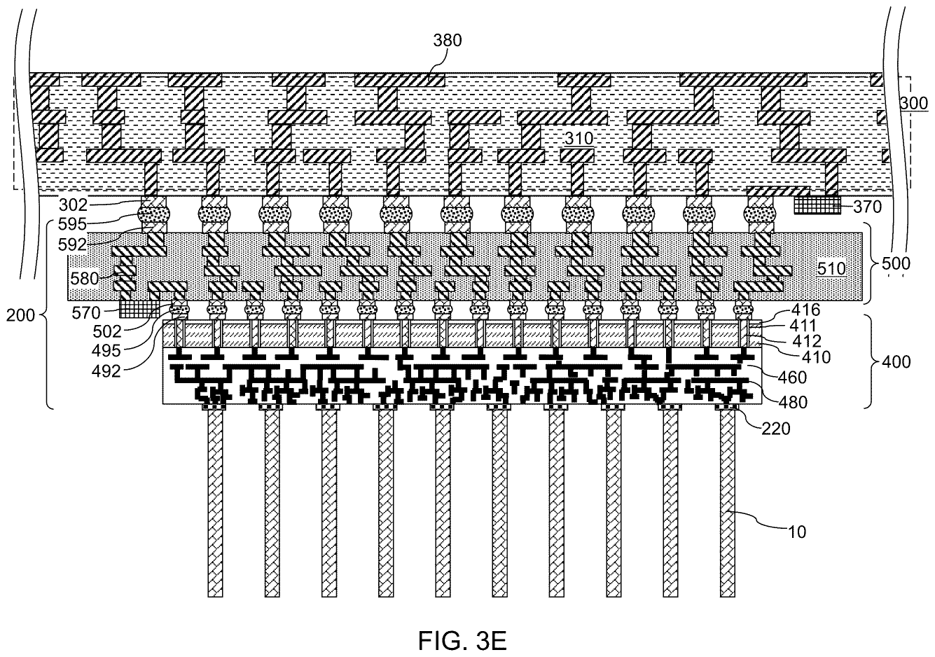

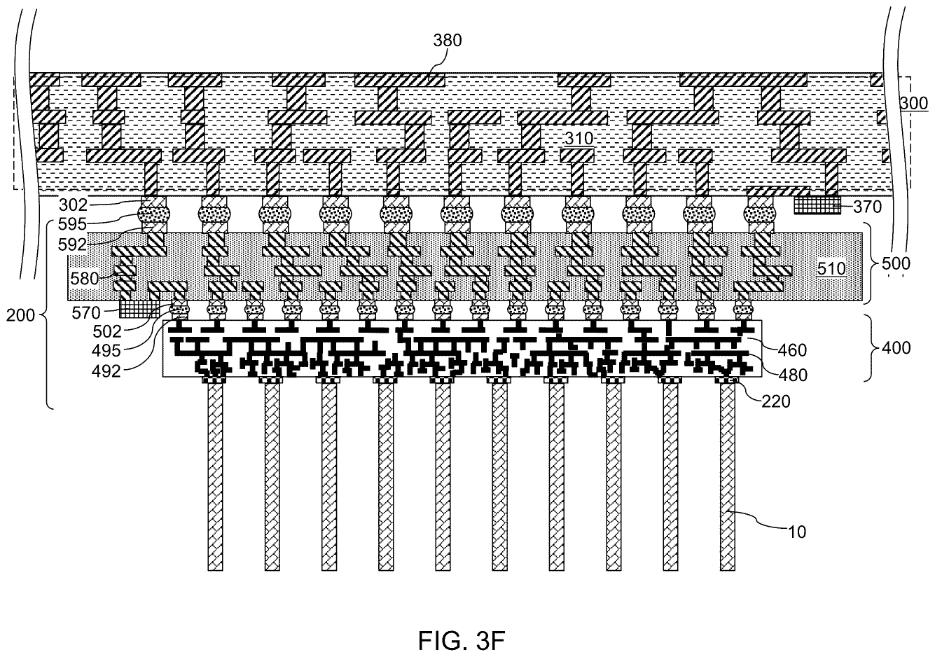

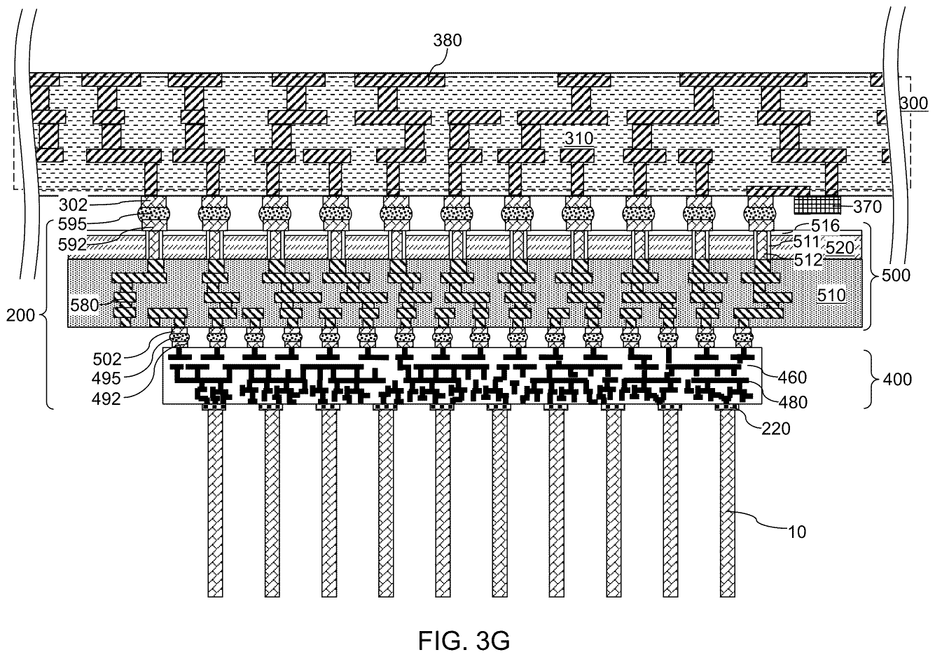

FIG. 3A is a vertical cross-sectional view of a first exemplary probe assembly (100, 200, 60, 300, 50) according to an embodiment of the present disclosure. FIG. 3B is a horizontal cross-sectional view along the horizontal plane B-B′ of the first exemplary probe assembly (100, 200, 60, 300, 50) of FIG. 3A. The vertical plane A-A′ in FIG. 3B is the cut plane of the vertical cross-sectional view of FIG. 3A. FIG. 3C is a horizontal cross-sectional view along the horizontal plane C-C′ of the first exemplary probe assembly (100, 200, 60, 300, 50) of FIG. 3A. The vertical plane A-A′ in FIG. 3C is the cut plane of the vertical cross-sectional view of FIG. 3A. FIG. 3D is a horizontal cross-sectional view along the horizontal plane D-D′ of the first exemplary probe assembly (100, 200, 60, 300, 50) of FIG. 3A. The vertical plane A-A′ in FIG. 3D is the cut plane of the vertical cross-sectional view of FIG. 3A. FIG. 3E is a magnified view of an upper portion of a probe card within the first exemplary probe assembly (100, 200, 60, 300, 50) of FIG. 3A-3D. The first exemplary probe module assembly (10, 100, 200, 60, 300, 50) in FIG. 3A-3E may be incorporated as the probe module assembly (10, 100, 200, 60, 300, 50) in the embodiment test apparatus of FIG. 1. The first exemplary probe module assembly (10, 100, 200, 60, 300, 50) in FIG. 3A-3E incorporates the composite interface substrate 200 illustrated in FIGS. 2C and 2D.

Generally, a probe card 300 may be provided. The probe card 300 comprises a probe card substrate 310 and traces 380 formed within, or on, the probe card substrate 310. The probe card 300 comprises a plastic substrate with printed circuits and contact structures designed to interconnect the probe interface assembly (10, 100, 200, 60) to the tester electronics unit 800. The probe card 300 comprises signal and power pathways for transmission of signals and power between the probe interface assembly (10, 100, 200, 60) to the tester electronics unit 800. In one embodiment, the probe card 300 may comprise on-card bonding pads 302, which may comprise solder bonding pads. Electrical components 370, such as capacitors, resistors, inductors, or other passive electrical components known in the art, may be attached to a subset of the traces 380.

The composite interface substrate 200 described with reference to FIG. 2C may be attached to the probe card 300 through an array of interconnection structures 290, which may include an array of solder balls or may include an interposer including an array of vertical interconnection structures. For example, an array of solder material portions 595 may be used to bond the array of solder bonding pads 592 on the distal interface substrate 500 with the array of on-card bonding pads 302 of the probe card 300. In one embodiment, C4 bonding may be used to bond the composite interface substrate 200 to the probe card 300.

A probe support assembly 50 may be disposed on the probe card 300. The probe support assembly 50 is configured to structurally support and align the probe card during testing. The probe support assembly 50 may comprise a stiffener 52 including an opening therein, a pusher 54 configured to fit into the opening in the stiffener 52, a backer having a greater lateral extent than the opening in the stiffener 52 and configured to support the backside, i.e., the upside, of the pusher 54, and a bridge beam 58 that is configured to provide structural reinforcement and flexibility.

The stiffener 52 maintains the rigidity of the probe support assembly 50 by preventing unwanted bending or flexing of the probe card 300. By creating a more robust connection between the probe card 300 and the probe support assembly 50, the stiffener 52 ensures that the probe module assembly (10, 100, 200, 60, 300, 50) remains stable during high-frequency testing, where small movements may impact signal accuracy.

The pusher 54, which fits into the opening in the stiffener 52, is designed to exert a controlled force on the probe needles 10 in order to ensure proper alignment and contact with a device under test (DUT), which may be a semiconductor die in a semiconductor wafer. The backer 56 supports the backside of the pusher 54. The backer provides additional structural support to the probe needles 10, and helps distribute the mechanical load evenly across the probe needles 10. The combination of the pusher 54 and the backer 56 reduces the likelihood of deformation under stress, thus ensuring that the probe needles 10 remain precisely aligned throughout the testing process.

The bridge beam 58 may be configured to allow for controlled vertical movement of the pusher 54 while maintaining alignment and stability under mechanical and thermal stresses. The bridge beam 58 within the probe support assembly 50 serves to enhance the mechanical stability of the probe module assembly (10, 100, 200, 60, 300, 50). The shape of the bridge beam 58 may be optimized to mitigate deflection under load. The probe support assembly 50 of the present disclosure may be used to provide precise alignment of probe needles 10 and to minimize mechanical deformation in the probe needles 10 to maintain signal integrity and to provide reliable testing of the DUT to be used.

The combination of the stiffener 52, the pusher 54, the backer 56, and the bridge beam 58 may be assembled in a manner that minimizes the tilting of the top surface of the bridge beam 58 relative to the bottom surface of the stiffener 52. Thus, the probe support assembly 50 of the present disclosure may be formed by assembling at least the pusher 54, the backer 56 along a vertical direction. Generally, the probe support assembly 50 comprises a vertical stack including, from bottom to top, a pusher 54 and a backer 56 is disposed on the probe card 300. The combination of the composite interface substrate 200, the probe card 300, and the probe support assembly 50 may be attached to a tester head 920.

A plate assembly 100 is provided. The plate assembly 100 may include an upper guide plate 20 which may include an upper array of upper holes 21 therethrough, a lower guide plate 80 may include a lower array of lower holes 81 therethrough, and a dielectric spacer plate 30 located between the upper guide plate 20 and the lower guide plate 80 and comprising a respective opening 31 therethrough. The lower guide plate 80 may be vertically spaced from the upper guide plate 20 by a dielectric spacer plate 30. The upper guide plate 20 includes an upper array of upper holes 21 therethrough, the lower guide plate 80 includes a lower array of lower holes 81 therethrough, and the dielectric spacer plate 30 comprises an opening 31 therethrough.

In one embodiment, the dielectric spacer plate 30 may comprise at least two guide openings 39 therethrough, and at least two fixture elements 92 may vertically extend through the guide opening 39 within the dielectric spacer plate 30. In one embodiment, the upper guide plate 20 comprises at least two threaded openings 29 therethrough, and the lower guide plate 80 comprises at least two lower guide openings 89 therethrough. In one embodiment, each of the at least two fixture elements 92 may vertically extend through a respective one of the lower guide openings 89 and through an opening 39 within the dielectric spacer plate 30, and may engage the thread of a respective one of the threaded openings 29.

An array of probe needles 10 may be inserted into the plate assembly 100. Each of the probe needles 10 may be inserted from the top side of the plate assembly 100 through the array of upper holes 21 in the upper guide plate 20, through the opening 31 in the dielectric spacer plate 30, and through the array of lower holes 81 in the lower guide plate 80. The probe needles 10 may be arranged as a two-dimensional periodic array of probe needles 10. Each of the probe needles may have a wider probe needle tail having a diameter greater than the diameter of the holes in the upper guide plate 20. The probe needles 10 may be inserted from the top side into the plate assembly 100, and the smaller diameter of the holes in the upper guide plate 20 relative to the diameter of the probe needle tails prevent the probe needles 10 from falling through the holes in the upper guide plate 20.

The plate assembly 100 may be attached to the printed circuit board 300 through the jig 60. The fixture elements 62 may be used to affix the plate assembly 100 to the printed circuit board 300 while a jig 60 is interposed between the plate assembly 100 and the printed circuit board 300. The fixture elements 62 may be adjusted to apply pressure to the array of probe needles 10 such that the array of probe needles 10 pushed against the probe contact pads 220. The plate assembly 100 may be used to align the array of probe needles 10 to the probe contact pads 220, and to attach the array of probe needles 10 to the probe contact pads 220. The array of probe needles 10 may be disposed directly on the probe contact pads 220. In one embodiment, the dielectric spacer plate 30 may include an outer periphery and an inner periphery that is laterally surrounded by, and is spaced from, the outer periphery. The dielectric spacer plate 30 laterally surrounds each probe needle 10 within the array of probe needles 10.

The jig 60 may be employed to attach the plate assembly 100 to the bottom side of the probe card 300. The jig 60 may laterally surround the composite interface substrate 200. The jig 60 may be provided with mechanical features designed to provide mechanical stability to the plate assembly 100. In a non-limiting illustrative example, the jig 60 may comprise threaded holes configured to mate with fixture elements 62, which may be bolts or screws. Optionally, the bottom surface of the composite interface substrate 200 may be provided with additional mechanical features designed to provide attachment of the plate assembly 100. In a non-limiting illustrative example, the composite interface substrate 200 may comprise additional threaded holes configured to mate with additional fixture elements 92, which may be bolts or screws.

In one embodiment, the composite interface substrate 200 may include at least two mating fixture elements configured to mate with the fixture elements 62. For example, the composite interface substrate 200 may include two or more threaded holes configured to accommodate, and form a stable mechanical support for, a thread of a bolt which may form a respective fixture element 62. In an illustrative example, the at least two fixture elements 62 may include at least two threaded bolts or at least two screws.

Thus, the probe module assembly (10, 100, 200, 60, 300, 50) comprises a probe card assembly (10, 100, 200, 60, 300) and a probe support assembly 50. The probe card assembly (10, 100, 200, 60, 300) includes a probe card 300 with integrated circuits and a probe interface assembly (10, 100, 200, 60).

Referring to FIG. 3F, a first alternative configuration of the first exemplary probe assembly is illustrated, which may be derived from the first exemplary probe assembly illustrated in FIG. 3A-3E by modifying the composite interface substrate 200. Specifically, the proximal interface substrate 400 may be modified to remove the combination of the silicon layer 410, the dielectric liners 411, the TSV structure 412, and the backside insulating layer 416. In this embodiment, the metallic bonding pads 492 may be formed directly on a horizontal surface of the first dielectric material layers 460 and a subset of the first metal interconnect structures 480.

Referring to FIG. 3G, a second alternative configuration of the first exemplary probe assembly is illustrated, which can be derived from the first exemplary probe assembly illustrated in FIG. 3A-3E by modifying the composite interface substrate 200. Specifically, the proximal interface substrate 400 may be modified to remove the combination of the silicon layer 410, the dielectric liners 411, the TSV structure 412, and the backside insulating layer 416. Further, the distal interface substrate 500 may include a silicon layer 520 embedding dielectric liners 511 and through-substrate via (TSV) structure 512. Each TSV structure 512 may be laterally surrounded by a respective dielectric liner 511, and may contact a respective one of the second metal interconnect structures 580. The silicon layer 520 may be located directly on a horizontal surface of the high-hardness dielectric layer 510. An insulating layer 516 may be provided on the side of the silicon layer 520 that faces the printed circuit board 300. In this embodiment, first metallic bonding pads 502 of the distal interface substrate 500 may be formed on the second metal interconnect structures 580, and second metallic bonding pads 592 of the distal interface substrate 500 may be formed on the insulating layer 516 and on end surfaces of the TSV structures 512. The metallic bonding pads 492 of the proximal interface substrate 400 may be formed directly on a horizontal surface of the first dielectric material layers 460 and a subset of the first metal interconnect structures 480.

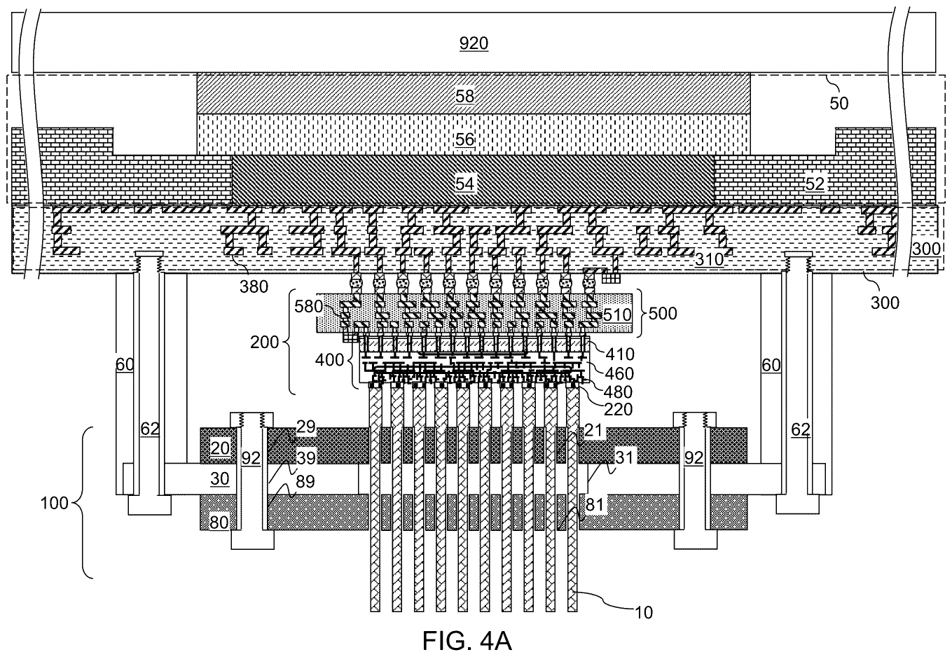

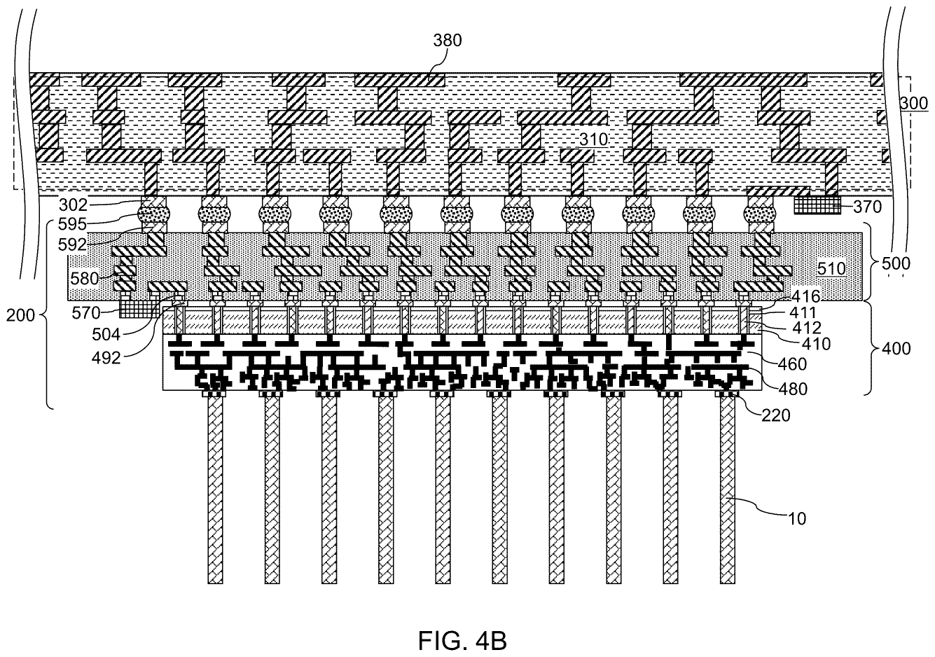

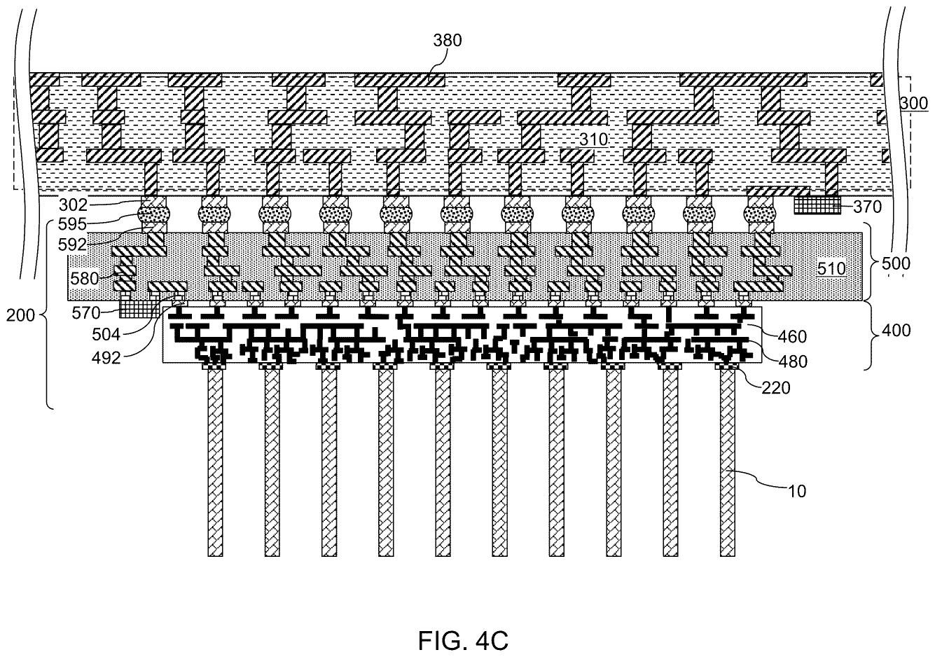

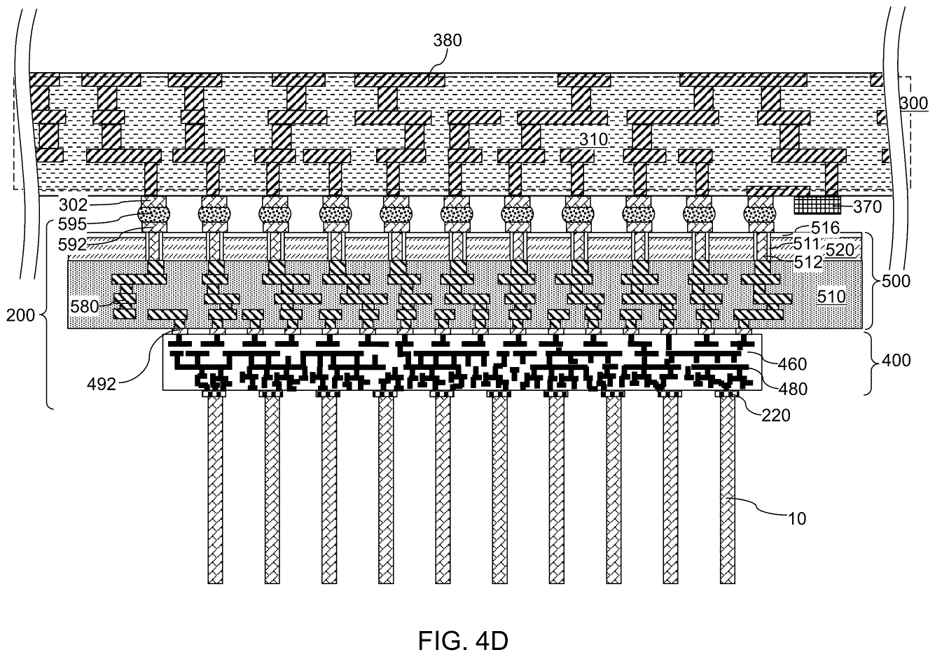

FIG. 4A is a vertical cross-sectional view of a second exemplary probe assembly (100, 200, 60, 300, 50) according to an embodiment of the present disclosure. FIG. 4B is a magnified view of an upper portion of a probe card within the second exemplary probe assembly (100, 200, 60, 300, 50) of FIG. 4A.

Referring to FIGS. 4A and 4B, the second exemplary probe assembly (100, 200, 60, 300, 50) may be derived from the first exemplary probe assembly (100, 200, 60, 300, 50) by using a different bonding method to provide bonding between the proximal interface substrate 400 and the distal interface substrate 500. In one embodiment, the distal interface substrate 500 may be bonded to the proximal interface substrate 400 by joining first metal bonding structures of the proximal interface substrate 400 to second metal bonding structures of the distal interface substrate 500 via metal-to-metal bonding. In this embodiment, the proximal interface substrate 400 comprises first metal bonding structures, the distal interface substrate 500 comprises second metal bonding structures, and metal-to-metal bonding may be performed between the first metal bonding structures and the second metal bonding structures such that the proximal interface substrate 400 is bonded to the distal interface substrate 500.

For example, the proximal interface substrate 400 and the distal interface substrate 500 may be bonded to each other through metal-to-metal bonding such as copper-to-copper bonding. In this embodiment, a subset of the second metal interconnect structures 580 that face the proximal interface substrate 400 may be configured as metal pads 504 (such as copper pads) having physically exposed surfaces. The metallic bonding pads 494 of the proximal interface substrate 400 may be configured for metal-to-metal bonding such as copper-to-copper bonding. The metallic bonding pads 494 of the proximal interface substrate 400 may be bonded to the metal pads 504 of the distal interface substrate 500 via direct metal-to-metal bonding such as copper-to-copper bonding.

In metal-to-metal bonding, mating pairs of metal surfaces are brought into direct contact with each other, and are annealed at an elevated temperature to induce atomic diffusion of metal atoms across the bonding interface. In this embodiment, grains of the metal within a first metal portion on one side may grow across a planar plane defining an initial contact area between two metal portions into a surface region of a second metal portion. Thus, the grain boundaries of the two metal portions are modified such that a subset of the grain boundaries cross over the planar plane that defines the initial contact area. The anneal temperature and the duration of the anneal process may be selected to induce sufficient metal diffusion across the initial bonding interface. In embodiments in which copper-to-copper bonding is used, the resulting bond may exhibit near-bulk electrical conductivity and mechanical robustness across the interface, making it especially suitable for reliable interconnects. In embodiments in which copper-to-copper bonding is used, the anneal temperature may be in a range from 200° C. to 400° C., and the duration of the anneal process may be in a range from 20 minutes to 120 minutes, although lesser or greater durations may also be used.

Referring to FIG. 4C, a first alternative configuration of the second exemplary probe assembly is illustrated, which may be derived from the second exemplary probe assembly illustrated in FIGS. 4A and 4B by modifying the composite interface substrate 200. Specifically, the proximal interface substrate 400 may be modified to remove the combination of the silicon layer 410, the dielectric liners 411, the TSV structure 412, and the backside insulating layer 416. In this embodiment, the metallic bonding pads 492 of the proximal interface substrate 400 may be formed directly on a horizontal surface of the first dielectric material layers 460 and a subset of the first metal interconnect structures 480, and may be bonded to metal pads 504 of the distal interface substrate 500 by metal-to-metal bonding. The metallic bonding pads 492 of the proximal interface substrate 400 may directly contact the high-hardness dielectric layer 510.

Referring to FIG. 4D, a second alternative configuration of the second exemplary probe assembly is illustrated, which may be derived from the second exemplary probe assembly illustrated in FIGS. 4A and 4B by modifying the composite interface substrate 200. Specifically, the proximal interface substrate 400 may be modified to remove the combination of the silicon layer 410, the dielectric liners 411, the TSV structure 412, and the backside insulating layer 416. Further, the distal interface substrate 500 may include a silicon layer 520 embedding dielectric liners 511 and through-substrate via (TSV) structure 512. Each TSV structure 512 may be laterally surrounded by a respective dielectric liner 511, and may contact a respective one of the second metal interconnect structures 580. The silicon layer 520 may be located directly on a horizontal surface of the high-hardness dielectric layer 510. An insulating layer 516 may be provided on the side of the silicon layer 520 that faces the printed circuit board 300. In this embodiment, first metallic bonding pads 502 of the distal interface substrate 500 may be formed on the second metal interconnect structures 580, and second metallic bonding pads 592 of the distal interface substrate 500 may be formed on the insulating layer 516 and on end surfaces of the TSV structures 512. The metallic bonding pads 492 of the proximal interface substrate 400 may be formed directly on a horizontal surface of the first dielectric material layers 460 and a subset of the first metal interconnect structures 480. In this configuration, the metallic bonding pads 492 of the proximal interface substrate 400 may be formed directly on a horizontal surface of the first dielectric material layers 460 and a subset of the first metal interconnect structures 480, and can be bonded to a subset of the second metal interconnect structures 580 of the distal interface substrate 500 by metal-to-metal bonding. The metallic bonding pads 492 of the proximal interface substrate 400 may directly contact the high-hardness dielectric layer 510.

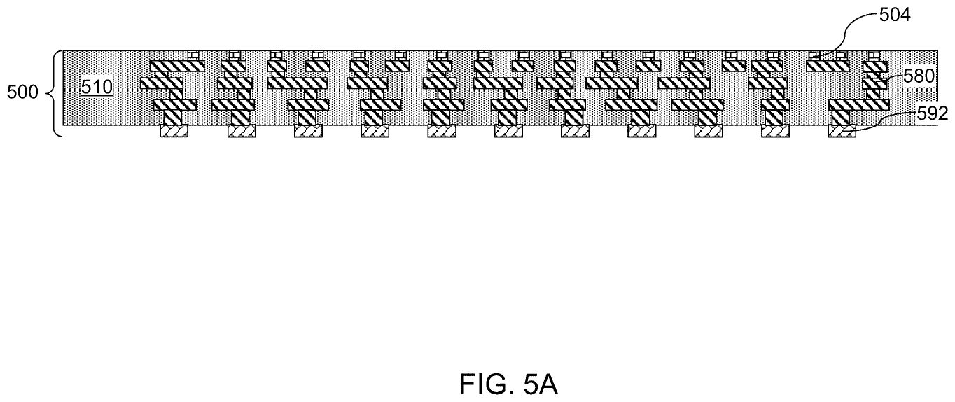

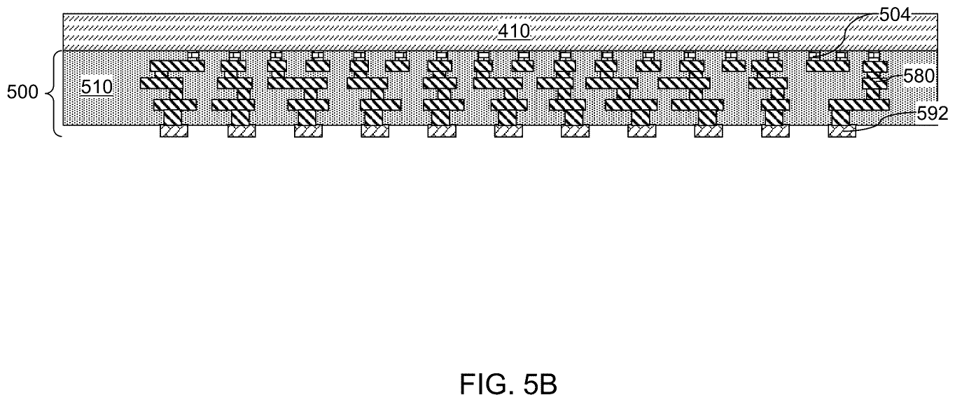

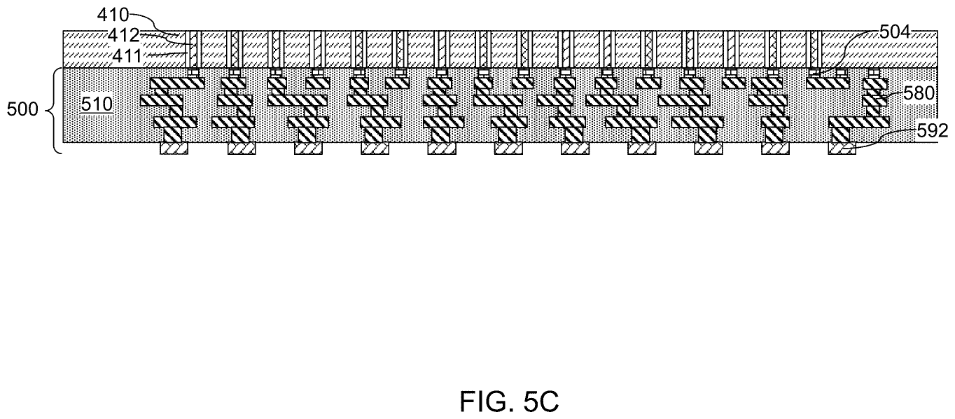

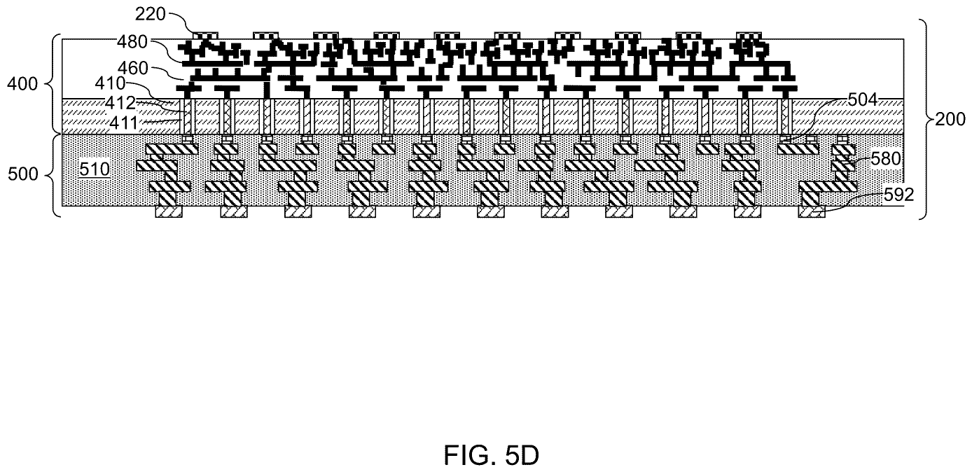

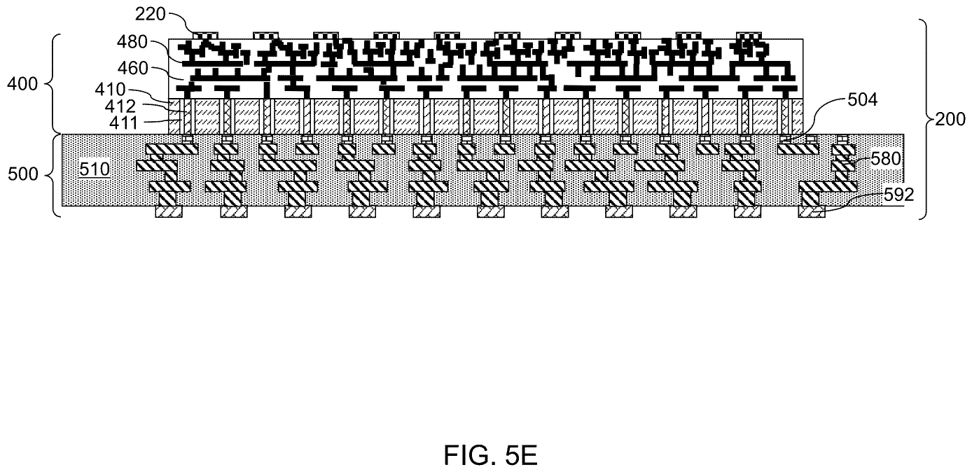

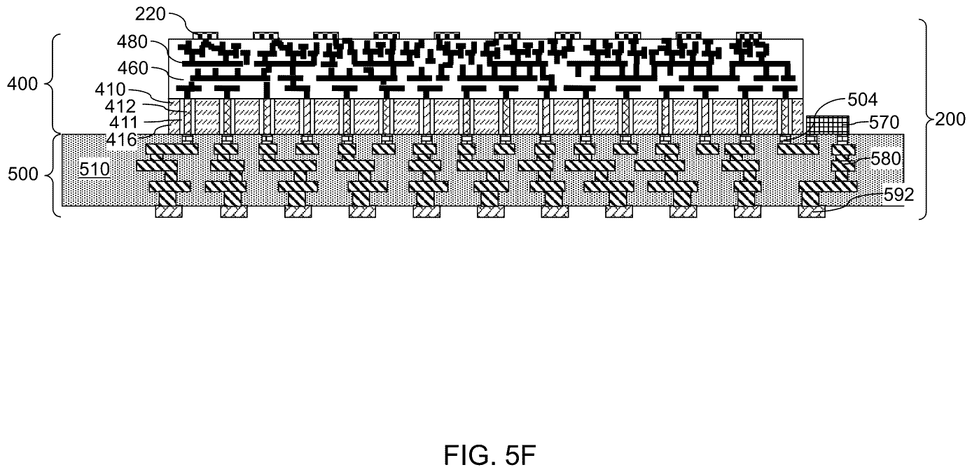

FIG. 5A-5F are sequential vertical cross-sectional views of an exemplary structure that is converted into a composite interface substrate 200 according to an embodiment of the present disclosure.

Referring to FIG. 5A, a distal interface substrate 500 is illustrated, which may be the same as the distal interface substrate 500 used in the second exemplary probe assembly (100, 200, 60, 300, 50) illustrated in FIGS. 4A and 4B. The distal interface substrate 500 may comprise metallic bonding pads 592 on one side, and may comprise metal pads 504 embedded within the high-hardness dielectric layer 510 on another side.

Referring to FIG. 5B, a silicon layer 410 may be formed directly on the distal interface substrate 500 and the metal pads 504. In one embodiment, the silicon layer 410 may be grown on the distal interface substrate 500 by performing a silicon deposition process, such as a silicon epitaxy process. The silicon layer 410 may be polycrystalline. Alternatively, in embodiments in which the high-hardness dielectric layer 510 comprises a single crystalline dielectric material such as single crystalline aluminum oxide, the silicon layer 410 may comprise single crystalline material portions that are epitaxially aligned to the single crystalline structure of the high-hardness dielectric layer 510. Yet alternatively, the silicon layer 410 may be bonded to the horizontal surface of the distal interface substrate 500 by performing a semiconductor-to-insulator bonding. For example, the distal interface substrate 500 may comprise silicon oxide, and an anneal process may be performed to induce silicon-to-silicon oxide bonding. The anneal temperature may be in a range from 200° C. to 600° C. in this embodiment. In one embodiment, the entirety of the silicon layer 410 may be a single crystalline silicon layer.

Referring to FIG. 5C, deep trenches may be formed through the silicon layer 410. Top surfaces of the metal pads 504 may be physically exposed at the bottom of the deep trenches. In one embodiment, the area of each deep trench may be greater than the area of a respective underlying metal pad 504 such that the periphery of the top surface of the underlying metal pad 504 is laterally offset inward relative to the periphery of the bottom surface of the respective deep trench. A dielectric liner 411 having a tubular configuration and a through-substrate via (TSV) structure 412 may be formed within each deep trench. Top surfaces of the dielectric liners 411 and the TSV structures 412 may be coplanar with the top surface of the silicon layer 410.

Referring to FIG. 5D, first metal interconnect structures 480 and first dielectric material layers 460 may be formed over the silicon layer 410. A proximal interface substrate 400 may be formed. The combination of the proximal interface substrate 400 and the distal interface substrate 500 constitutes a composite interface substrate 200.

Referring to FIG. 5E, peripheral regions of the proximal interface substrate 400 may be optionally removed.

Referring to FIG. 5F, electrical components 570 may be optionally attached to a subset of the metal pads 504, for example, by soldering.

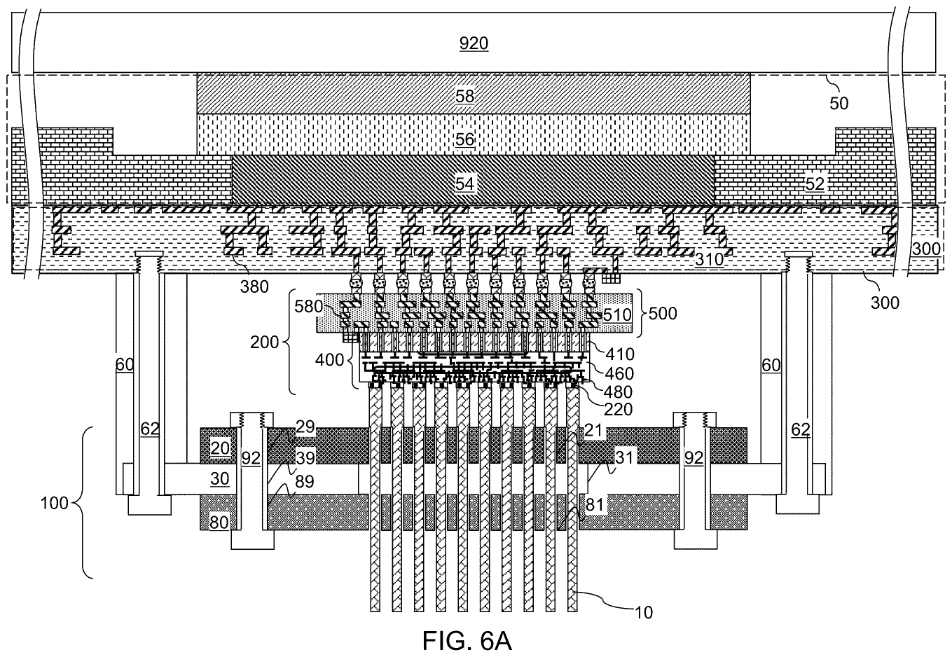

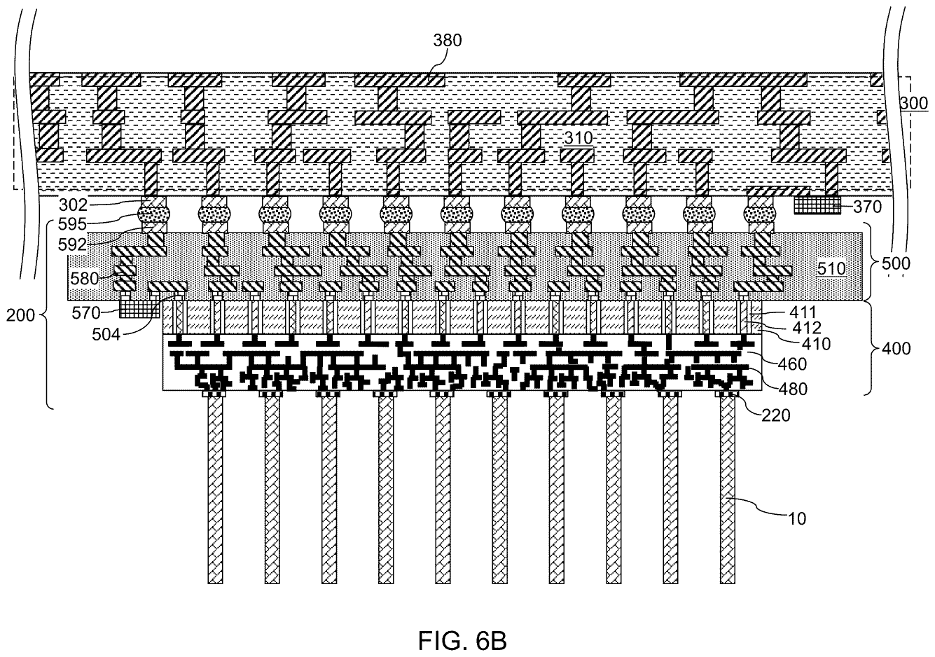

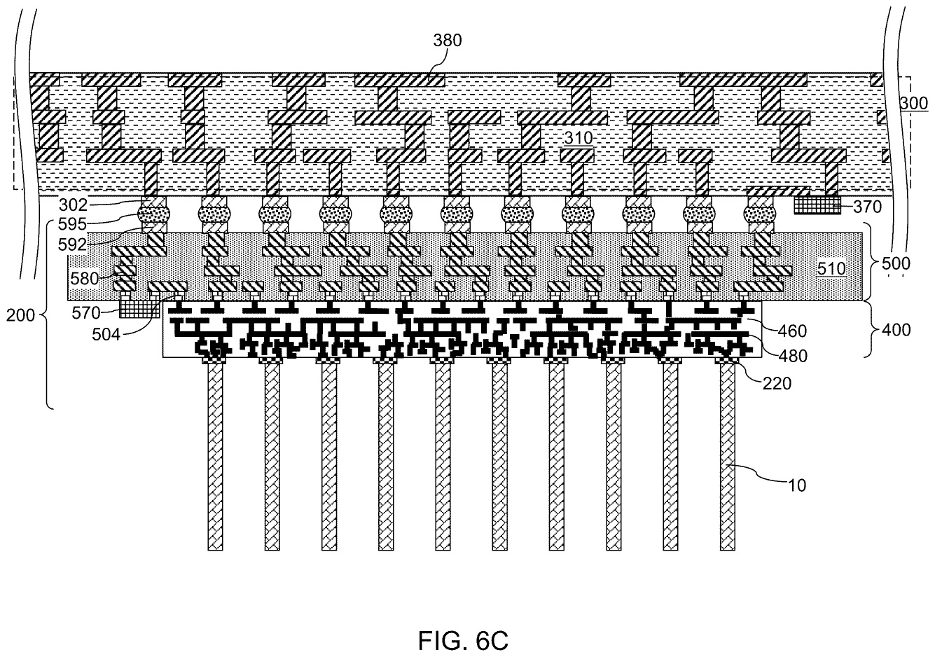

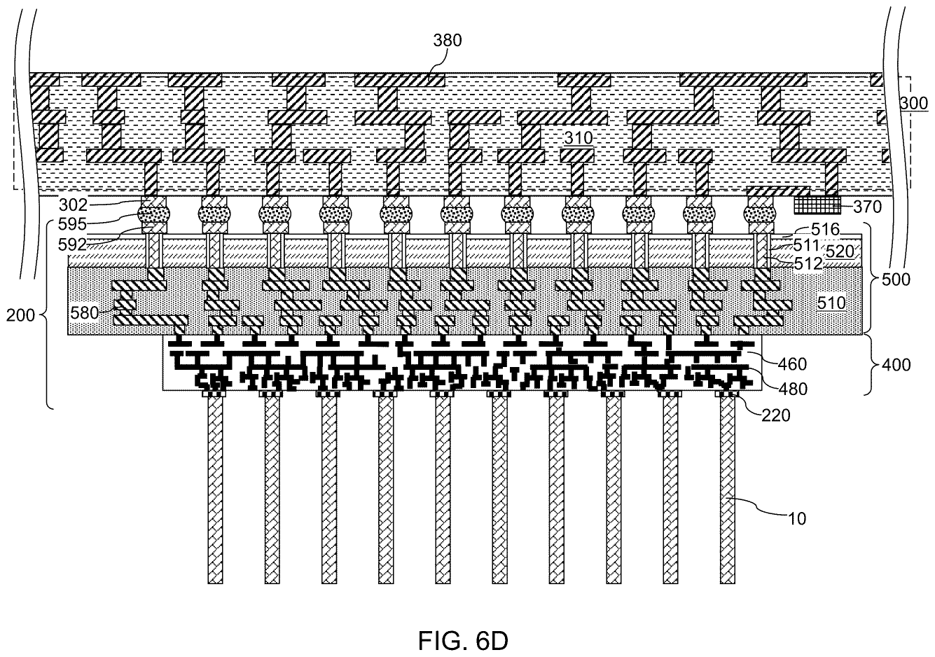

FIG. 6A is a vertical cross-sectional view of a third exemplary probe assembly (100, 200, 60, 300, 50) according to an embodiment of the present disclosure. FIG. 6B is a magnified view of an upper portion of a probe card within the third exemplary probe assembly (100, 200, 60, 300, 50) of FIG. 5A. The third exemplary probe assembly (100, 200, 60, 300, 50) incorporates the composite interface substrate 200 of FIG. 5F.

Referring to FIGS. 6A and 6B, the second exemplary probe assembly (100, 200, 60, 300, 50) may be derived from the first exemplary probe assembly (100, 200, 60, 300, 50) by bonding the proximal interface substrate 400 to the distal interface substrate 500 such that the silicon layer 410 is in direct contact with the distal interface substrate 500. In one embodiment, the silicon layer 410 is formed directly on the distal interface substrate 500.

Referring to FIG. 6C, a first alternative configuration of the third exemplary probe assembly is illustrated, which may be derived from the third exemplary probe assembly illustrated in FIGS. 6A and 6B by modifying the composite interface substrate 200. Specifically, the proximal interface substrate 400 may be modified to remove the combination of the silicon layer 410, the dielectric liners 411, the TSV structure 412, and the backside insulating layer 416. In this embodiment, a subset of the first metal interconnect structures 480 of the proximal interface substrate 400 may be bonded to metal pads 504 of the distal interface substrate 500 by metal-to-metal bonding. The first dielectric material layers 460 of the proximal interface substrate 400 may directly contact the high-hardness dielectric layer 510.

Referring to FIG. 6D, a second alternative configuration of the third exemplary probe assembly is illustrated, which can be derived from the third exemplary probe assembly illustrated in FIGS. 6A and 6B by modifying the composite interface substrate 200. Specifically, the proximal interface substrate 400 may be modified to remove the combination of the silicon layer 410, the dielectric liners 411, the TSV structure 412, and the backside insulating layer 416. Further, the distal interface substrate 500 may include a silicon layer 520 embedding dielectric liners 511 and through-substrate via (TSV) structure 512. Each TSV structure 512 may be laterally surrounded by a respective dielectric liner 511, and may contact a respective one of the second metal interconnect structures 580. The silicon layer 520 may be located directly on a horizontal surface of the high-hardness dielectric layer 510. An insulating layer 516 may be provided on the side of the silicon layer 520 that faces the printed circuit board 300. In this embodiment, metallic bonding pads 592 of the distal interface substrate 500 may be formed on the insulating layer 516 and on end surfaces of the TSV structures 512. A subset of the first metal interconnect structures 480 of the proximal interface substrate 400 may be bonded to a subset of the second metal interconnect structures 580 of the distal interface substrate 500 by metal-to-metal bonding. The first dielectric material layers 460 of the proximal interface substrate 400 may directly contact the high-hardness dielectric layer 510.

Referring collectively to FIG. 1-6D, a test apparatus comprising a probe assembly (100, 200, 60, 300, 50) is provided. The probe assembly (100, 200, 60, 300, 50) comprises: a composite interface substrate 200 comprising a bonded stack of a proximal interface substrate 400 and a distal interface substrate 500, wherein the proximal interface substrate 400 comprises a silicon layer 410, first metal interconnect structures 480, and probe contact pads 220, and wherein the distal interface substrate 500 comprises a high-hardness dielectric layer 510 and second metal interconnect structures 580, wherein the high-hardness dielectric layer 510 has a Vickers hardness greater than 500 HV; a printed circuit board 300 that is attached to the distal interface substrate 500; and an array of probe needles 10 attached to the probe contact pads 220 and vertically extending downward from the probe contact pads 220.

In one embodiment, the test apparatus comprises an array of solder material portions 495 providing solder bonding between the proximal interface substrate 400 and the distal interface substrate 500. In one embodiment, the proximal interface substrate 400 is bonded to the distal interface substrate 500 by metal-to-metal bonding. In one embodiment, the silicon layer 410 is in direct contact with the distal interface substrate 500. In one embodiment, the silicon layer 410 may be formed directly on the distal interface substrate 500. In one embodiment, the proximal interface substrate 400 comprises an array of through-substrate via (TSV) structures 412 vertically extending through the silicon layer 410.

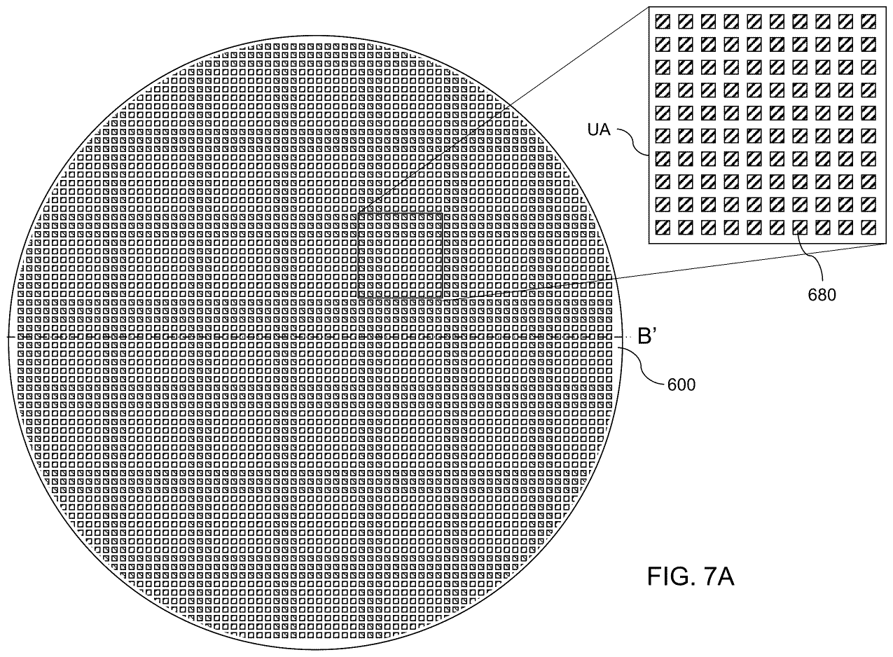

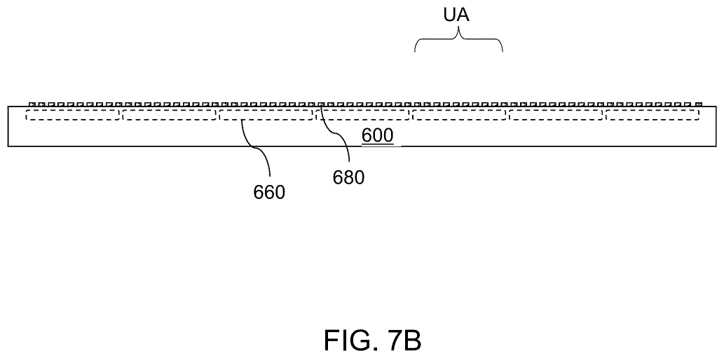

Referring to FIGS. 7A and 7B, a semiconductor wafer 600 including a two-dimensional array of semiconductor dies 660 is illustrated. Each semiconductor die 660 may comprise a respective array of test pads 680. The pattern of a single semiconductor die 660 may be a unit pattern UA, which is repeated within the area of the semiconductor wafer 600 with a two-dimensional periodicity.

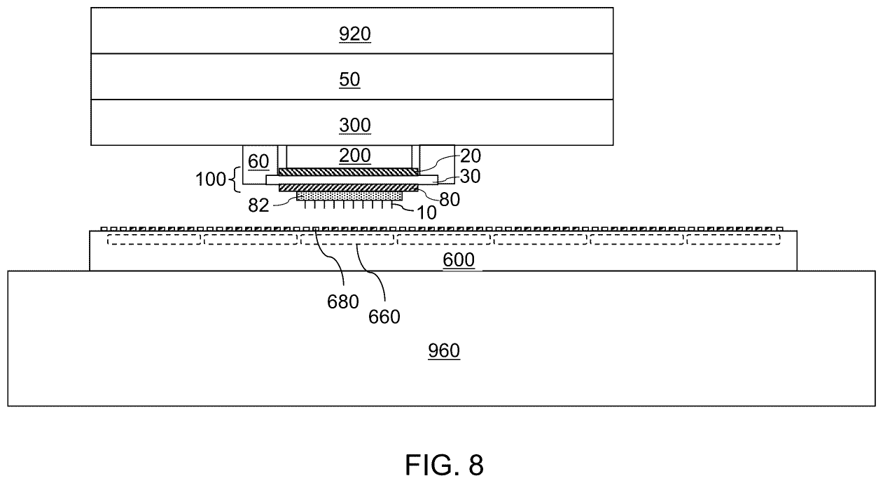

FIG. 8 is a vertical cross-sectional view of a portion of the test apparatus of FIG. 1 during testing of a semiconductor die 660 in the semiconductor wafer 600. Generally, a semiconductor wafer 600 including semiconductor devices may be positioned under the array of probe needles 10. The array of probe needles 10 may be aligned to, and may be disposed on, test pads 680 on the semiconductor wafer 600. Data representing electrical characteristics of the semiconductor devices may be generated by running a test program. In this embodiment, the semiconductor dies 660 may be the device under test 980 illustrated in FIG. 1

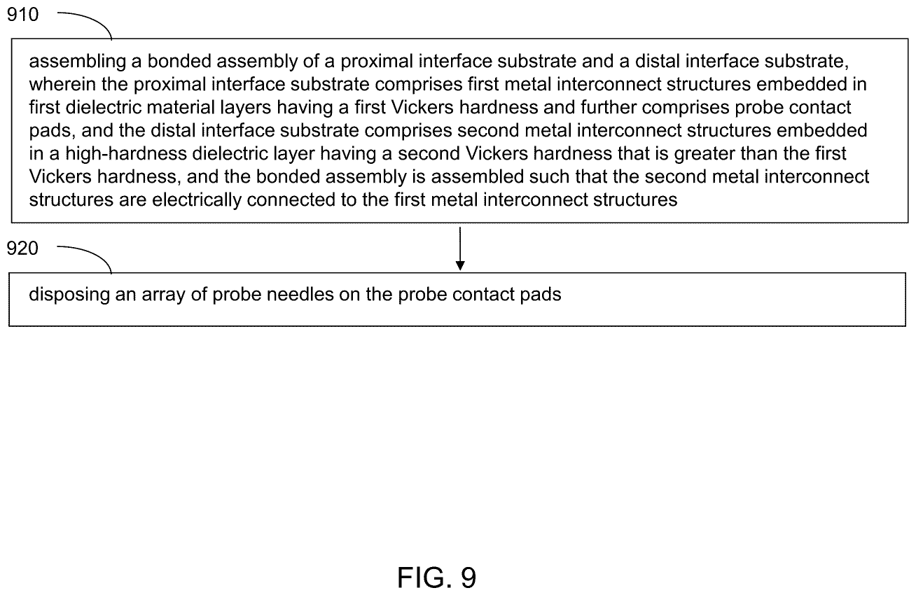

FIG. 9 is a first flowchart that illustrates the general processing steps for operating a test apparatus according to an aspect of the present disclosure.

Referring to step 910 and FIGS. 1, 2A-2C, 5A-5F and 9, a bonded assembly of a proximal interface substrate 400 and a distal interface substrate 500 is assembled. The proximal interface substrate 400 comprises first metal interconnect structures 480 embedded in first dielectric material layers 460 having a first Vickers hardness and further comprises probe contact pads 220, and the distal interface substrate 500 comprises second metal interconnect structures 580 embedded in a high-hardness dielectric layer 510 having a second Vickers hardness that is greater than the first Vickers hardness. The second Vickers hardness may be greater than 500 HV. In some embodiments, the high-hardness dielectric layer 510 may have a greater Vickers hardness than silicon oxide, which is 1,000 HV. In some embodiments, the high-hardness dielectric layer 510 may have a greater Vickers hardness than silicon oxide. In some embodiments, the high-hardness dielectric layer 510 has a lower coefficient of thermal expansion than silicon. The bonded assembly is assembled such that the second metal interconnect structures 580 are electrically connected to the first metal interconnect structures 480.

Referring to step 920 and FIGS. 2D, 3A-4D, and 6A-9, an array of probe needles 10 may be disposed on the probe contact pads 220.

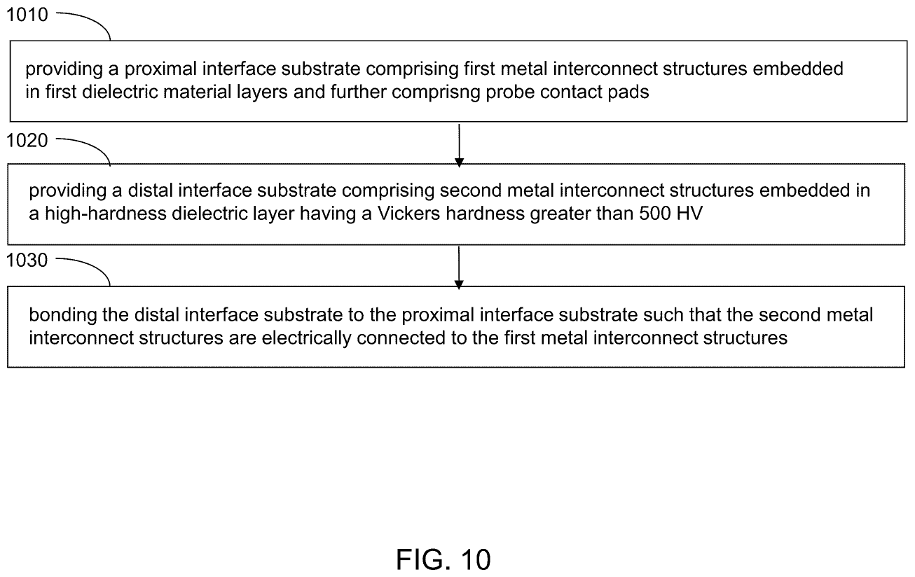

FIG. 10 is a second flowchart that illustrates the general processing steps for manufacturing a test apparatus according to an aspect of the present disclosure.

Referring to step 1010 and FIGS. 2A, 2B, and 10, a proximal interface substrate 400 comprising first metal interconnect structures 480 embedded in first dielectric material layers 460 and further comprising probe contact pads 220 may be provided.

Referring to step 1020 and FIG. 2C, a distal interface substrate 500 comprising second metal interconnect structures 580 embedded in a high-hardness dielectric layer 510 having a Vickers hardness greater than 500 HV is provided. In some embodiments, the high-hardness dielectric layer 510 may have a greater Vickers hardness than silicon oxide. In some embodiments, the high-hardness dielectric layer 510 has a lower coefficient of thermal expansion than silicon.

Referring to step 1030 and FIGS. 2C and 2D, the distal interface substrate 500 may be bonded to the proximal interface substrate 400 such that the second metal interconnect structures 580 are electrically connected to the first metal interconnect structures 480.

According to an embodiment of the present disclosure, a test apparatus comprising a probe assembly (100, 200, 60, 300, 50) is provided. The probe assembly (100, 200, 60, 300, 50) comprises: a composite interface substrate 200 comprising a bonded stack of a proximal interface substrate 400 and a distal interface substrate 500, wherein the proximal interface substrate 400 comprises first metal interconnect structures 480 embedded in first dielectric material layers 460 having a first Vickers hardness and further comprises probe contact pads 220, and wherein the distal interface substrate 500 comprises second metal interconnect structures 580 embedded in a high-hardness dielectric layer 510 having a second Vickers hardness that is greater than the first Vickers hardness; a printed circuit board 300 that is attached to the distal interface substrate 500; and an array of probe needles 10 attached to the probe contact pads 220 and vertically extending downward from the probe contact pads 220.

The embodiments of the present disclosure provide advantages in enhancing the performance and reliability of semiconductor testing. By incorporating a composite interface substrate comprising a bonded assembly of a proximal interface substrate and a distal interface substrate, the disclosed probe card assembly achieves improved mechanical and thermal stability. Specifically, the distal interface substrate, characterized by a Vickers hardness greater than 500 HV, minimizes warpage and deformation under stress, ensuring consistent probe-to-pad alignment. The use of materials with low coefficients of thermal expansion (CTE) mitigates dimensional changes due to thermal fluctuations, enhancing the precision of electrical connections. Moreover, the integration of fine-pitch second metal interconnect structures and bonding techniques, such as solder bonding or metal-to-metal bonding, provides higher circuit density and electrical conductivity. These advancements address the limitations of conventional organic substrates, such as inadequate flatness, high thermal expansion, and reduced reliability, enabling higher throughput, greater accuracy, and longer operational lifetimes in semiconductor testing.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of operating a test apparatus, the method comprising:
assembling a bonded assembly of a proximal interface substrate and a distal interface substrate, wherein the proximal interface substrate comprises first metal interconnect structures embedded in first dielectric material layers having a first Vickers hardness and further comprises probe contact pads, and the distal interface substrate comprises second metal interconnect structures embedded in a high-hardness dielectric layer having a second Vickers hardness that is greater than the first Vickers hardness, and the bonded assembly is assembled such that the second metal interconnect structures are electrically connected to the first metal interconnect structures; and
disposing an array of probe needles on the probe contact pads.

2. The method of claim 1, wherein the bonded assembly is provided by:
providing the proximal interface substrate;
providing the distal interface substrate; and
bonding the proximal interface substrate with the distal interface substrate.

3. The method of claim 2, wherein bonding the distal interface substrate to the proximal interface substrate comprises performing solder bonding such that the proximal interface substrate is bonded to the distal interface substrate via an array of solder material portions.

4. The method of claim 2, wherein bonding the distal interface substrate to the proximal interface substrate comprises joining first metal bonding structures of the proximal interface substrate to second metal bonding structures of the distal interface substrate via metal-to-metal bonding.

5. The method of claim 2, wherein the proximal interface substrate is bonded to the distal interface substrate by metal-to-metal bonding.

6. The method of claim 1, wherein the probe contact pads is provided directly on a subset of the first metal interconnect structures.

7. The method of claim 1, wherein:
the proximal interface substrate comprises an array of through-substrate via (TSV) structures; and
the second metal interconnect structures are electrically connected to a respective one of the TSV structures upon bonding the distal interface substrate to the proximal interface substrate.

8. The method of claim 1, wherein the high-hardness dielectric layer comprises a material that is selected from silicon nitride, silicon carbide, a mullite-cordierite composite, and a ceramic material.

9. The method of claim 1, further comprising:
disposing a probe support assembly over the printed circuit board; and
attaching a combination of the printed circuit board, a composite interface substrate, the array of probe needles, and the probe support assembly to a tester head.

10. The method of claim 1, further comprising:
positioning a semiconductor wafer including semiconductor devices under the array of probe needles;
inducing physical contact between the array of probe needles and test pads on the semiconductor wafer; and
generating electrical data representing electrical characteristics of the semiconductor devices.

11. A test apparatus comprising a probe assembly, the probe assembly comprising:
a composite interface substrate comprising a bonded stack of a proximal interface substrate and a distal interface substrate, wherein the proximal interface substrate comprises first metal interconnect structures embedded in first dielectric material layers having a first Vickers hardness and further comprises probe contact pads, and wherein the distal interface substrate comprises second metal interconnect structures embedded in a high-hardness dielectric layer having a second Vickers hardness that is greater than the first Vickers hardness;
a printed circuit board that is attached to the distal interface substrate; and
an array of probe needles attached to the probe contact pads and vertically extending downward from the probe contact pads.

12. The test apparatus of claim 11, further comprising an array of solder material portions providing solder bonding between the proximal interface substrate and the distal interface substrate.

13. The test apparatus of claim 11, wherein the proximal interface substrate is bonded to the distal interface substrate by metal-to-metal bonding.

14. The test apparatus of claim 11, wherein the proximal interface substrate is bonded to the distal interface substrate through solder-mediated bonding.

15. The test apparatus of claim 11, wherein the proximal interface substrate comprises an array of through-substrate via (TSV) structures vertically extending through a silicon layer.

16. A method manufacturing a test apparatus, comprising:
providing a proximal interface substrate comprising first metal interconnect structures embedded in first dielectric material layers and further comprising probe contact pads;
providing a distal interface substrate comprising second metal interconnect structures embedded in a high-hardness dielectric layer having a Vickers hardness greater than 500 HV; and
bonding the distal interface substrate to the proximal interface substrate such that the second metal interconnect structures are electrically connected to the first metal interconnect structures.

17. The method of claim 16, wherein:
the proximal interface substrate comprises first solder bonding pads;
the distal interface substrate comprises second solder bonding pads; and
the method comprises performing solder bonding using an array of solder material portions between the first solder bonding pads and the second solder bonding pads such that the proximal interface substrate is bonded to the distal interface substrate.

18. The method of claim 16, wherein:
the proximal interface substrate comprises first metal bonding structures;
the distal interface substrate comprises second metal bonding structures; and
the method comprises metal-to-metal bonding between the first metal bonding structures and the second metal bonding structures such that the proximal interface substrate is bonded to the distal interface substrate.

19. The method of claim 16, wherein the proximal interface substate is formed directly on the distal interface substrate.

20. The method of claim 16, wherein:
the probe contact pads are located directly on a subset of the first metal interconnect structures; and
the method comprises disposing an array of probe needles directly on the probe contact pads.
